(19) United States
(12) Patent Application Publication
(10) Pub. No.: US 2009/0273413 A1
(43) Pub. Date: Nov. 5, 2009

(54) POWER DIVIDER INTEGRATED CIRCUIT

(76) Inventors: Wen Hui Zhang, Nashua, NH (US); Jeffrey H. Bienstock, Nashua, NH (US)

Correspondence Address: CHRISTOPHER P. MAIORANA, P.C., 24840 HARPER SUITE 100, ST. CLAIR SHORES, MI, 48080, US

(21) Appl. No.: 12/113,880

(22) Filed: May 1, 2008

(51) Int. Cl. H01P 5/12; H03H 7/48; H03H 7/38; H05K 3/00

(52) U.S. Cl. 333/124; 29/846; 333/136

(57) ABSTRACT

A power divider integrated circuit is provided. The power divider integrated circuit includes a substrate and a power divider circuit formed on one side of the substrate.

### BACKGROUND OF THE INVENTION

This invention relates generally to power dividers, and more particularly, to a power divider integrated circuit.

Power dividers are often used in wireless communication systems, such as microwave, radio frequency (RF), cellular phone systems, etc. having multi-wave or multi-channel operation. Power dividers may be formed using different processes. For example, integrated circuit power dividers may be formed using semiconductor processing and one or more semiconductor materials, such as Gallium Arsenide (GaAs). In these semiconductor structures, vias or through holes are formed that typically provide a path to ground from a top surface of the structure to a bottom surface. The formation of the vias, for example, gold plated through holes to ground, is often not reliable. For example, the size of the via and the plating within the via is often difficult to precisely control. Thus, the formation of the vias results in a more complicated and expensive process. Moreover, the vias are often the main cause of unwanted parasitics, which degrade the performance of the power divider.

One type of common power divider is a Wilkinson power divider, which may be used in microwave communication systems to divide power among numerous ports. This type of power divider may be used, for example, to divide power at higher frequency operation (e.g., 25 GHz). The Wilkinson power divider may be formed from distributed components, especially when the power divider is to be used at higher frequencies where discrete resistive and capacitive components cannot be used for many applications because the associated parasitics would be too high with discrete components. Accordingly, resistance and reactance is distributed along the circuit using transmission-line elements. However, for communication applications at lower frequencies (e.g., 1.75 GHz to 2.5 GHz), the distributed components would be much too large for many communication applications (e.g., integration into a cellular phone) because the dimensions of the distributed components increase as the signal wavelength increases at these lower frequencies. For example, the distributed components could not be placed on a die to be used in a portable device. Accordingly, instead of using distributed components, lumped components are used. These lumped components include discrete resistors, capacitors, inductors, etc. However, when using lumped components, for example, to form a power divider integrated circuit using known methods, several vias to ground must be provided. Accordingly, the performance of the power divider is degraded as the power divider suffers from the problems described above.

### BRIEF DESCRIPTION OF THE INVENTION

In accordance with an exemplary embodiment, a power divider integrated circuit is provided. The power divider integrated circuit includes a substrate and a power divider circuit formed on one side of the substrate.

In accordance with another exemplary embodiment, a power divider circuit topology is provided that includes an input port and a plurality of branches each corresponding to a different one of a plurality of output ports. A plurality of capacitors within each of a different one of the plurality of circuit branches is connected at a first end to a common node. The power divider circuit further includes an inductor within each of the different one of the plurality of circuit branches and connected to a second end of each of the plurality of capacitors between the capacitor within each respective one of the plurality of circuit branches and the input port. The power divider circuit also includes a resistor within each of the different one of the plurality of circuit branches connected between the common node and a corresponding output port.

In accordance with yet another exemplary embodiment, a method of forming a power divider integrated circuit is provided. The method includes forming a substrate and depositing metal on one side of the substrate to define a plurality of components of a power divider circuit.

### BRIEF DESCRIPTION OF THE DRAWINGS

FIG. 1 is a simplified block diagram of a power divider that may be implemented using various embodiments of the invention.

FIG. 2 is a schematic diagram of a circuit topology for a power divider constructed in accordance with various embodiments of the invention.

FIG. 3 is a top plan view of a portion of a power divider integrated circuit constructed in accordance with various embodiments of the invention.

FIG. 4 is a side elevation view of a portion of a power divider integrated circuit constructed in accordance with various embodiments of the invention inside a lead frame.

FIG. 5 is a graph illustrating the matching characteristics of the circuit topology of FIG. 2.

FIG. 6 is a graph illustrating the isolation characteristics of the circuit topology of FIG. 2.

FIG. 7 is a graph illustrating signal loss of the circuit topology of FIG. 2.

FIG. 8 is a Smith chart illustrating the normalized input impedance of the circuit topology of FIG. 2.

### DETAILED DESCRIPTION OF THE INVENTION

For simplicity and ease of explanation, the invention will be described herein in connection with various embodiments thereof. Those skilled in the art will recognize, however, that the features and advantages of the various embodiments may be implemented in a variety of configurations. It is to be understood, therefore, that the embodiments described herein are presented by way of illustration, not of limitation.

As used herein, an element or step recited in the singular and proceeded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property. Additionally, the arrangement and configuration of the various components described herein may be modified or changed, for example, replacing certain components with other components or changing the order or relative positions of the components.

Various embodiments of the invention provide a power divider, for example, a four-way power divider that uses a circuit topology that eliminates vias to ground. In particular, in an integrated circuit chip design, the various embodiments provide a power divider without any on-chip vias. The power divider may be formed using any suitable integrated circuit fabrication process. For example, one such suitable process is a heterolithic microwave integrated circuit (HMIC) fabrication method as described in U.S. Pat. No. 6,150,197. However, any suitable integrated circuit fabrication process may be used.

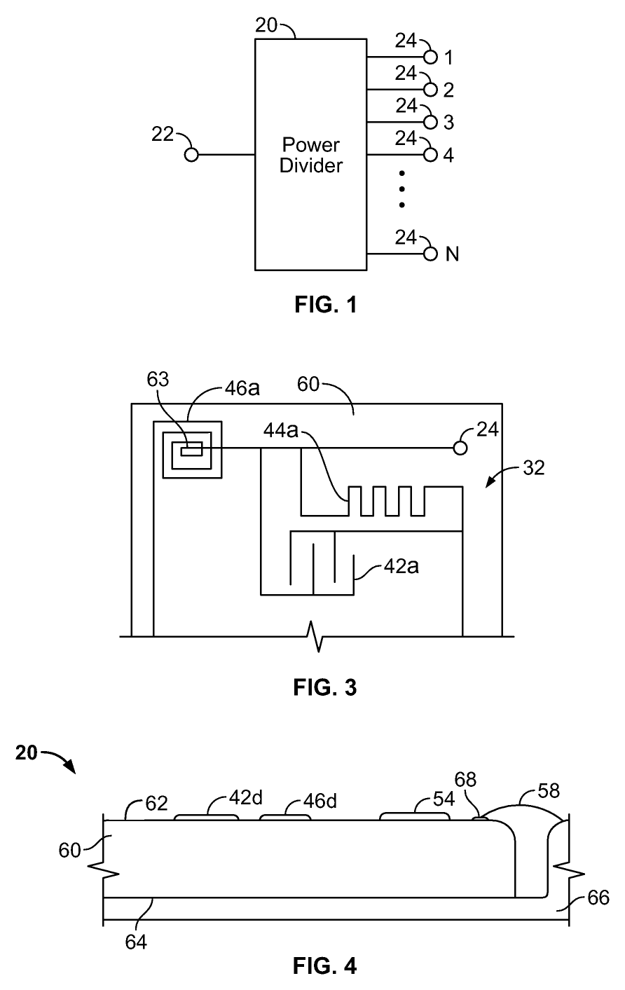

The various embodiments may be implemented to form different types of power dividers. For example, using the circuit topology of the various embodiments, an in-phase power divider, such as a Wilkinson power divider, or a quadrature power divider (90 degree shift) may be constructed. In general, as shown in FIG. 1, a power divider 20 includes an input port 22 that receives input power from a power source. The power divider 20 includes a plurality of output ports 24 with the power from the input port 22 divided between the output ports 24. The power is typically divided equally among the plurality of output ports 24. In a Wilkinson power divider, for example, isolation is provided among each of the plurality of output ports 24 and the impedances at the input port 22 and plurality of output ports 24 are typically designed to be equal to the characteristic impedance of the device in which the power divider 20 is to be used (e.g., microwave communication device).

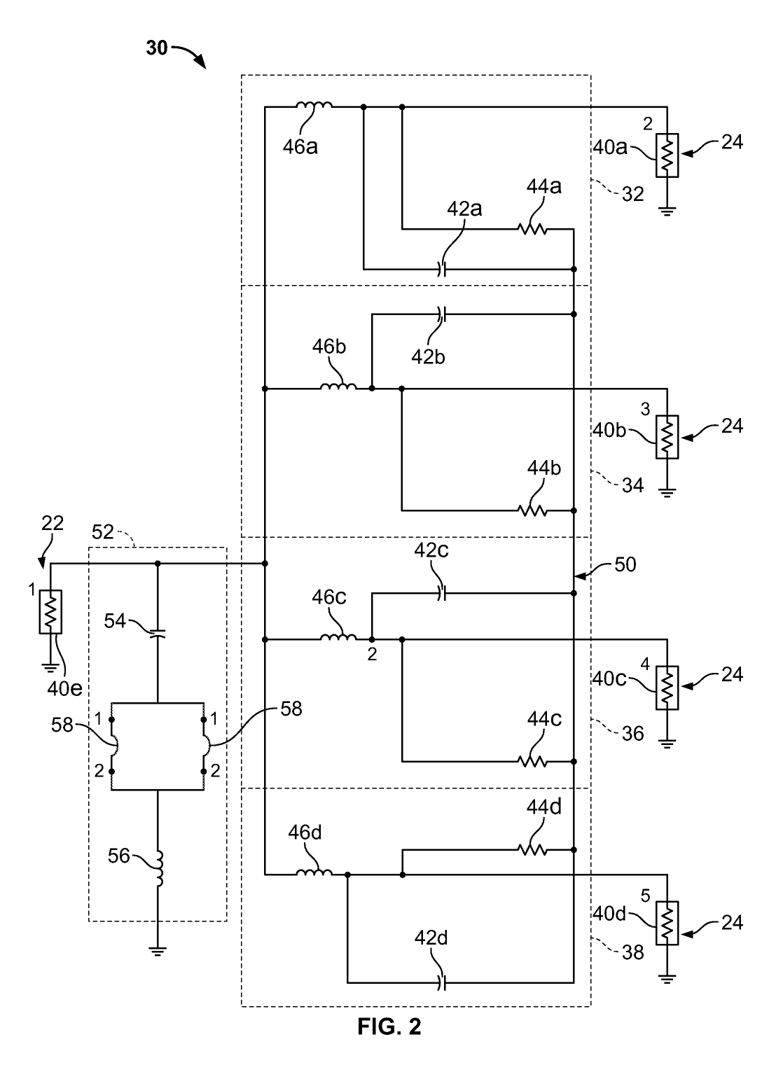

A circuit topology 30 for forming the power divider 20 is shown in FIG. 2. The circuit topology 30 may be fabricated as part of an integrated circuit having no vias through the integrated circuit material. Accordingly, no through holes to ground are needed using the circuit topology 30. It should be noted that although the circuit topology 30 illustrates a four-way power divider, the circuit topology 30 may be extended or used to form any N-way power divider, where N is a value greater than one. The circuit topology 30 defines a balanced topology having a first circuit branch 32, a second circuit branch 34, a third circuit branch 36 and a fourth circuit branch 38. The circuit branches 32-38 define parallel circuits within the circuit topology 30 with each of the branches 32-38 corresponding to a different output port 24 of the power divider 20. Each of the outputs ports 24 is represented in the circuit topology 30 as a load termination 40a, 40,b, 40c and 40d, respectively in each of the branches 32-38. The load terminations 40a-40d in the embodiment shown are represented by 50 ohm load terminations. Accordingly, the power at the input port 22, represented by load termination 40e, is divided into each of the branches 32-38. Thus, in one embodiment, the output power at each of the load terminations 40a-40d is equal to one-fourth of the input power at the load termination 40e.

Each branch 32-38 of the circuit topology 30 includes a capacitor 42a, 42b, 42c and 42d, respectively. The capacitors 42a-42d are each connected at one end (e.g., a first end) to a common node 50 along with each of resistors 44a, 44b, 44c and 44d in each of the branches 32-28, respectively. In a typical topology, the end of the capacitors 42a-42d that are connected to the common node 50 are instead connected through a via to ground. Thus, the connection of the capacitors 42a-42d and the resistors 44a-44d form a floating node at the common node 50. The other end (e.g., second end) of each of the capacitors 40a-40d is connected to the input port 22 (represented by load termination 40e) through a corresponding inductor 46a, 46b, 46c and 46d in each of branches 32-38, respectively. It should be noted that each of the capacitors 40a-40d in the various embodiments may be, for example, metal-insulator-metal (MIM) capacitors. However, other types of capacitors may be used.

Referring again to the resistors 44a-44d, each of the resistors 44a-44d are connected between the common node 50 and the output ports 24 represented by the load terminations 40a-40d, respectively. In various embodiments, each of the resistors 44a-44d have a value of about 50 ohms. However, the values of the resistors 44a-44d may be changed as desired or needed, for example, for a particular application or operating characteristic.

The input port 22 is connected to a wye circuit (also commonly referred to as a star circuit) defined by the branches 32-38 through a circuit 52 having a capacitor 54 wire bonded to a parasitic lead frame represented by the inductor 56 using wire bonds 58. Thus, only one ground is needed for the circuit topology 30, which is accomplished in various embodiments by the wire bonding. It also should be noted that when the power divider 20 is formed, for example, on a die as described in more detail below, the capacitor 54 may be positioned towards the edge of the die to minimize the length of the wire bond needed to ground the connection.

In operation, a signal applied at the input port 22 is divided between four electrical paths defined by the four branches 32-38. Accordingly, a signal applied at the input port 22 represented by the load termination 40e is divided between the four branches 32-38 and the divided signal (e.g., one-fourth of the signal power) is output at each of the output ports 24 represented by the load terminations 40a-40d. The circuit topology 30 provides a balanced output between the input port 22 and the output ports 24. Moreover, the configuration of the circuit topology 30 provides isolation between each of the output ports 24 such that cross-talk or interference is minimized between the output ports 24.

As illustrated by the circuit topology 30, the power divider 20 is formed without any vias to ground, and in particular, no vias to ground are provided to each of the capacitors 42a-42d. The capacitors 42a-42d with the resistors 44a-44d are connected to the common node 50. It also should be noted that the circuit is a passive circuit having no active components, for example, diodes, transistors, etc.

As shown in FIG. 3, the various components of the circuit topology 30 for the power divider 20 may be formed from passive components on a substrate 60, for example, on a top surface of the substrate 60. It should be noted that only a portion of the circuit topology 30 on a portion of the substrate 60 is shown in FIG. 3, and in particular, one branch 32 of the power divider 20. However, the other branches 34-38 have similar components and connections.

The passive components may be formed on the substrate 60 using any known process, and in general may be deposited on, integrated with or embedded in the substrate 60. As an example, the substrate 60 and passive components may be formed as an integrated circuit using an HMIC process. Depending on the application, the HMIC process results in a power divider microwave integrated circuit that can be used, for example, for radio or cellular communications.

The passive components include the inductor 46a, which is formed on the substrate and configured in a spiral arrangement. For example, the inductor 46a may be formed by metal deposition on the top surface of the substrate 60. The metal forming the inductor 46a (and any of the other components of the circuit topology 30) may be any suitable metal, for example, gold or a titanium platinum gold (TiPtAu) composite that is deposited on the top surface of the substrate 60. It should be noted that the shape and size of the inductor 46a may be modified as desired or needed. For example, the inductor 46a, instead of being formed from metal spiral deposits, may be formed as a helical multi-layer structure or any other suitable configuration as is known. The inductor 46a, as is shown, includes an air bridge 63 to provide electrical connection from the center of the inductor 46a to the outer periphery, which in the circuit topology 30 connects to the other components in the branch 32, namely the capacitor 42a and the resistor 44a. The capacitor 42a is formed from a parallel plate configuration. However, it should be noted that the capacitor 42a may be formed in different configurations, for example, using metal deposits arranged as opposed electrical lines arranged in parallel (i.e., an interdigitated configuration). The resistor 44a is also formed from metal deposits arranged in a rectangular pattern or a meandering pattern as shown. However, other patterns and configurations may be formed as is known.

The inductor 46a is connected to the output port 24 (represented by the load termination 40a in FIG. 2). The output port 24 may be formed from a metal deposit shaped (e.g., circular or square in shape) to allow connection to a wire. It should be noted that the metal deposits (or metallizations) forming the components of the circuit topology 30 may be formed using any known process and shaped, sized and oriented based on, for example, the die to be formed from the substrate 60.

In various embodiments, the substrate 60 is formed entirely from glass using an HMIC process. As can be seen in FIG. 4, the substrate 60 may form a power divider integrated circuit 20 having no vias from a top surface 62 to a bottom surface 64 of the substrate. The components defining the circuit topology 30 are formed on the top surface 62 of the substrate 60 as described herein. Accordingly, the entire power divider integrated circuit 20 is formed on only one side of the substrate 60, for example, on the top surface 62 (or on multiple layers of the top surface 62). It should be noted that substrate 60 may be formed from materials other than glass or in addition to glass. For example, the substrate may be formed from silicon or a combination of silicon and glass. Different types of semiconductor materials may be used including, for example, gallium arsenide.

Moreover, the substrate 60 defining the integrated circuit may be mounted within a lead frame 66 or other suitable package, which may be based on the application or use for the power divider 20. The connection between the power divider 20, which may be an integrated circuit, and the lead frame 66 is provided by one or more wire bonds 58 as is shown. The wire bonding may be provided using processes in the art and connects the power divider 20 to ground through the lead frame 66. For example, in one embodiment a metallization 68 may be provided on the top surface 62 of the substrate 60 and connected to the capacitor 54 of the circuit 52 (both shown in FIG. 2). The metallization 68 is connected via wire bond 58 to the lead frame 66 to provide an electrical path to ground. It should be noted that depending on the application, the lead frame 66 may not be provided. When no lead frame 66 is provided, the power divider 20 is connected via wire bond 58 to any suitable grounding structure, element or reference to provide an electrical path to ground. It also should be noted that the wire bond 58 optionally may be connected directly to the capacitor 54. Thus, the power divider 20 is grounded via one or more wire bonds 58 without the use of a via or other through holes in the substrate 60.

The use of a substrate 60 formed from glass provides a low loss substrate (as opposed to GaAs) that provides minimal degradation in performance even with no vias at communication frequencies as illustrated in FIGS. 5 through 8. It should be noted that although the graphs in FIGS. 5 through 7 illustrate operation in a frequency range of 1.75 GHz to 2.3 GHz, similar performance results are achieved at other operating frequencies. It also should be noted that the reference to pairs of numbers on the vertical axis of the graphs in FIGS. 5 through 8 corresponds to the numbered connections in the circuit topology 30 of FIG. 2.

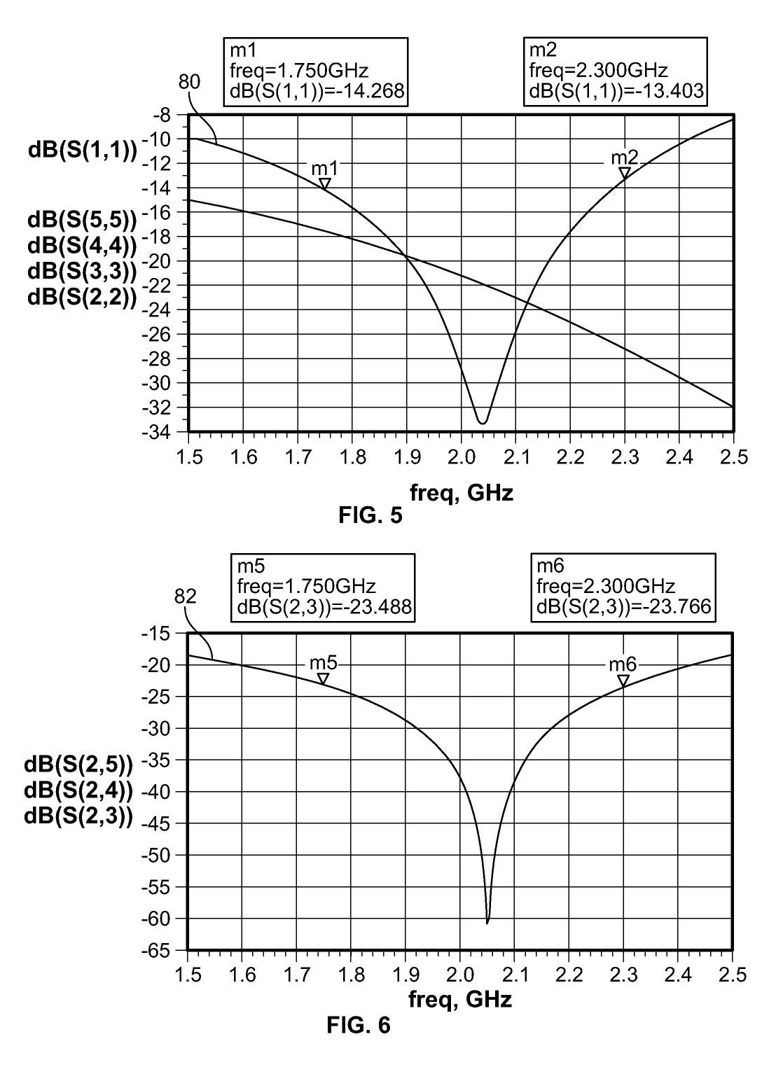

FIG. 5 illustrates the matching at each of the load terminations (40a-40e shown in FIG. 2). As can be seen, the reflected signal at each of the load terminations is small. In particular, at point m1 on the curve 80, the reflected power is about −14 dB at a frequency of 1.750 GHz. The reflected power at 2.300 GHz, as illustrated at point m2 on the curve 80, is about −13.5 dB. The isolation at the load termination provided by this embodiment is illustrated in FIG. 6, showing the isolation between load termination 40a and each of load terminations 40b-40d. As can be seen, at point m5 on the curve 82, the isolation is about −23.5 dB at 1.750 GHz and at point m6 the isolation is about −23.7 dB at 2.300 GHz.

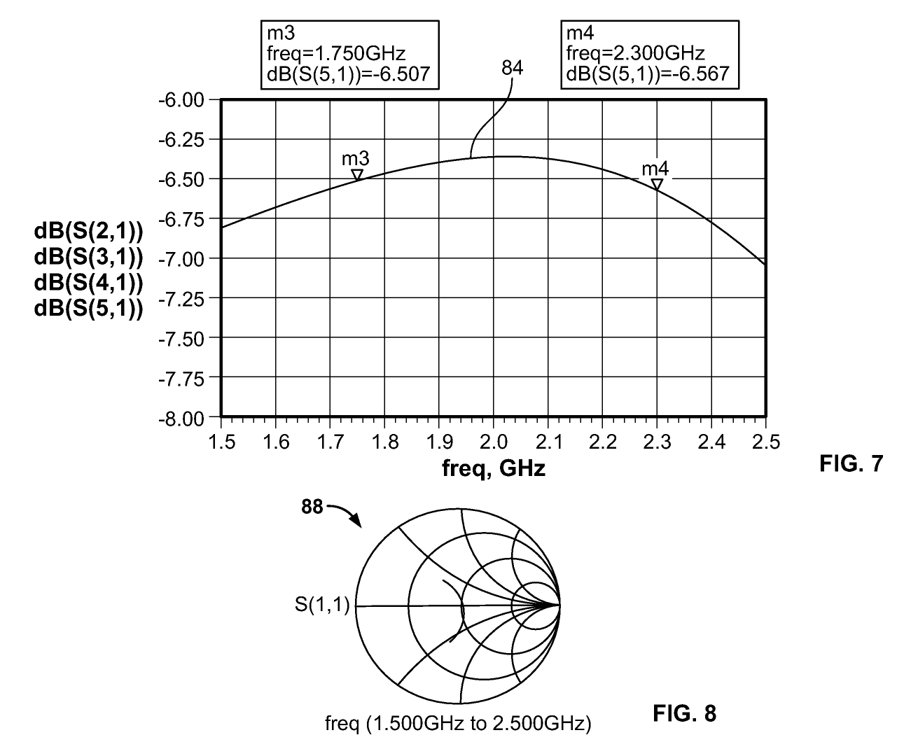

Signal loss is illustrated in FIG. 7, which shows the loss between the input port 22 (represented by load termination 40e) and each of the output ports 24 (represented by load terminations 40a-40d). As can be seen, the signal loss at point m3 on the curve 86 is about −6.5 dB (−0.5 dB above a lossless four-way power divider) at 1.750 GHz. The signal loss at point m4 on the curve 86 is about −6.5 dB at 2.300 GHz. Moreover, the port matching is illustrated in the Smith chart of FIG. 8 showing in two dimensions on a complex reflection coefficient plane plot 88 the scaled normalized impedance at the input port 22, which confirms the performance of the circuit topology 30 illustrated in FIGS. 5 through 7.

Thus, the various embodiments provide a circuit topology for a power divider implemented as part of an integrated circuit having no vias to ground. Only a single ground is needed, which may be provided using wire bonding. The elimination of vias in the substrate of the integrated circuit reduces unwanted parasitics, thus improving the performance of the power divider. Moreover, using an HMIC process, a mass produced cost-effective power divider integrated circuit may be provided. The circuit topology of the various embodiments also allows the power divider to be formed in a smaller overall area.

It should be noted that modifications and variations to the various embodiments are contemplated. For example, the positioning and size of the components, terminals and nodes may be modified based on the particular application, use, etc. The modification may be based on, for example, different desired or required operating characteristics.

Accordingly, it is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description.

The scope of the various embodiments of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A power divider integrated circuit comprising:
a substrate; and
a power divider circuit formed on one side of the substrate.

2. A power divider integrated circuit in accordance with claim 1 further comprising a wire bond connecting the power divider circuit to a grounding structure.

3. A power divider integrated circuit in accordance with claim 2 wherein the grounding structure is a lead frame.

4. A power divider integrated circuit in accordance with claim 1 wherein the substrate forms a heterolithic microwave integrated circuit (HMIC) having no vias therethrough.

5. A power divider integrated circuit in accordance with claim 1 wherein the substrate comprises only glass.

6. A power divider integrated circuit in accordance with claim 1 wherein the power divider circuit comprises metal components on a top surface of the substrate.

7. A power divider integrated circuit in accordance with claim 1 wherein the power divider circuit is configured to operate with a floating node.

8. A power divider integrated circuit in accordance with claim 1 wherein the substrate defines an integrated circuit chip having no on-chip vias.

9. A power divider integrated circuit in accordance with claim 1 wherein the power divider circuit comprises a four-way power divider.

10. A power divider circuit topology comprising:
an input port;
a plurality of branches each corresponding to a different one of a plurality of output ports;
a capacitor within each of a different one of the plurality of circuit branches, each of the capacitors connected at a first end to a common node;
an inductor within each of the different one of the plurality of circuit branches, each of the inductors connected to a second end of each of the plurality of capacitors between the capacitor within each respective one of the plurality of circuit branches and the input port; and
a resistor within each of the different one of the plurality of circuit branches, each of the resistors connected between the common node and a corresponding output port.

11. A power divider circuit topology in accordance with claim 10 wherein the plurality of capacitors, inductors and resistors comprise passive components.

12. A power divider circuit topology in accordance with claim 10 further comprising a circuit connected to each of the plurality of circuit branches and configured to provide electrical grounding to each of the plurality of circuit branches.

13. A power divider circuit topology in accordance with claim 12 further comprising at least one wire bond connecting the circuit to ground.

14. A power divider circuit topology in accordance with claim 10 further comprising at least four circuit branches defining a four-way power divider.

15. A power divider circuit topology in accordance with claim 10 wherein the common node defines a floating node.

16. A power divider circuit topology in accordance with claim 10 wherein the plurality of capacitors, inductors and resistors are configured to operate in a frequency range of about 1.5 GHz to 2.5 GHz.

17. A method of forming a power divider integrated circuit, the method comprising:
forming a substrate; and
depositing metal on one side of the substrate to define a plurality of components of a power divider circuit.

18. A method in accordance with claim 17 further comprising wire bonding the power divider circuit to a grounding structure.

19. A method in accordance with claim 17 wherein forming the substrate comprises using a heterolithic microwave integrated circuit (HMIC) process.

20. A method in accordance with claim 17 wherein the substrate comprises only glass.
